(19) United States
(12) Patent Application Publication
(10) Pub. No.: US 2020/0084879 A1
(43) Pub. Date: Mar. 12, 2020

(54) ELECTRONIC DEVICE

(71) Applicant: Toshiba Memory Corporation, Minato-ku (JP)

(72) Inventor: Satoru FUKUCHI, Chigasaki (JP)

(73) Assignee: Toshiba Memory Corporation, Minato-ku (JP)

(21) Appl. No.: 16/298,511

(22) Filed: Mar. 11, 2019

(30) Foreign Application Priority Data
Sep. 7, 2018 (JP) 2018-168058

(51) Int. Cl. H05K 1/02

(52) U.S. Cl. CPC H05K 1/0224; H05K 2201/093; H05K 2201/098; H05K 2201/09336; H05K 2201/09672; H05K 2201/09309

(57) ABSTRACT

According to one or more embodiment, an electronic device includes a board. The board includes a first layer and a second layer. The first layer includes a first power supply pattern. The second layer includes a second power supply pattern. The second power supply pattern is electrically connected to the first power supply pattern. When viewed in a thickness direction of the board, half or more of the first power supply pattern overlaps the second power supply pattern, or at least a portion of the first power supply pattern overlaps a signal line provided in the second layer.

### CROSS-REFERENCE TO RELATED APPLICATION

This application is based upon and claims the benefit of priority from Japanese Patent Application No. 2018-168058 filed on Sep. 7, 2018; the entire contents of which are incorporated herein by reference.

### FIELD

Embodiments described herein relate generally to an electronic device.

### BACKGROUND

An electronic device including a board having a power supply pattern is known. Meanwhile, improvement in signal quality of the electronic device is expected.

### BRIEF DESCRIPTION OF THE DRAWINGS

FIG. 1 is a perspective view showing an electronic device according to a first embodiment.

FIG. 2 is a cross-sectional view of a circuit board taken along line F2-F2 shown in FIG. 1.

FIG. 3 is a perspective view showing the circuit board of the first embodiment.

FIG, 4 is a diagram showing an example of a relationship of a first resonance frequency with respect to a first longitudinal length of a first power supply pattern.

FIG. 5 is a perspective view showing a first modification of the circuit board of the first embodiment,

FIG. 6 is a perspective view showing a second modification of the circuit board of the first embodiment.

FIG. 7 is a perspective view showing a circuit board according to a second embodiment.

FIG. 8 is a perspective view showing a modification of the circuit board of the second embodiment.

### DETAILED DESCRIPTION

According to one or more embodiments, an electronic device includes a board. The board includes a first layer and a second layer. The first layer includes a first power supply pattern. The second layer includes a second power supply pattern. The second layer is electrically connected to the first power supply pattern. When viewed in a thickness direction of the board, half or more of the first power supply pattern overlaps the second power supply pattern, or at least a portion of the first power supply pattern overlaps a signal line provided in the second layer.

Hereinafter, an electronic device according to embodiments will be described with reference to the drawings. In the following description, components having the same or similar functions are denoted by the same reference numerals. Also, repeated explanations for these components may be omitted in some cases.

### First Embodiment

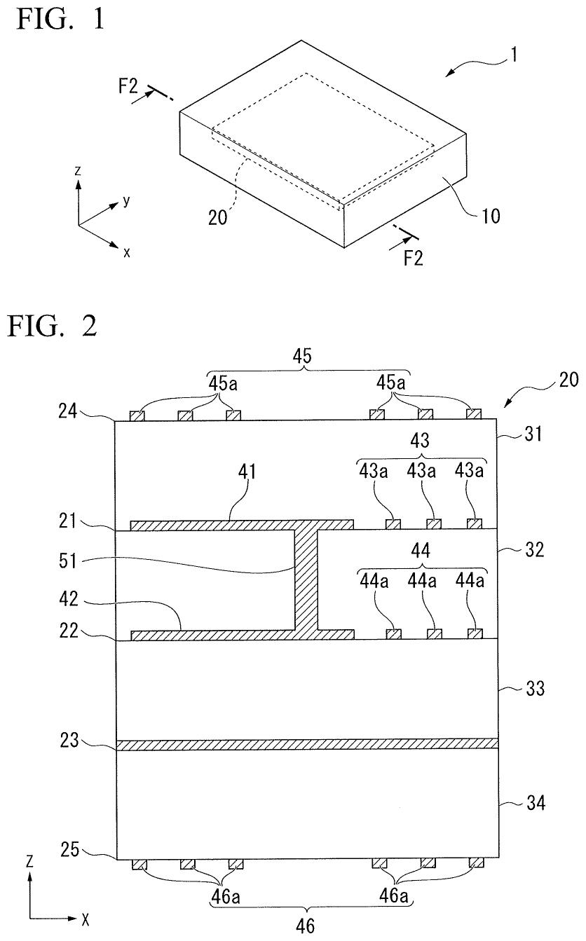

A first embodiment will be described with reference to FIGS, 1 to 6. FIG. 1 is a perspective view showing an electronic device 1 of the first embodiment.

The electronic device 1 includes a housing 10 and a circuit board 20 accommodated in the housing 10. The electronic device 1 is, for example, a solid state drive (SSD) or the like, but is not limited thereto.

The housing 10 is a box-shaped rigid member accommodating the circuit board 20. The housing 10 is, for example, in a shape of a thin rectangular body, and the housing 10 is made of, for example, plastic or metal.

The circuit board 20 is, for example, a printed circuit board on which a plurality of electronic components are mounted. The circuit board 20 may be a rigid board or a flexible board. The circuit board 20 is an example of a “board.”

Here, for convenience of explanation, definition will be performed using an x direction, a y direction, and a z direction. The x direction and the y direction are, for example, directions along a main surface of the circuit board 20. Here, the “main surface” means a surface having the largest area among surfaces of the circuit board 20 (for example, the circuit board 20 has two main surfaces facing opposite sides). The y direction is a direction that is different from (for example, is substantially perpendicular to) the x direction. The z direction is a direction that is different from (for example, is substantially perpendicular to) the x direction and the y direction, and is, for example, a direction normal to the main surface of the circuit board 20. For example, the z direction is a thickness direction of the circuit board 20. Shapes of the electronic device 1, the housing 10, and the circuit board 20 are not limited to a rectangular parallelepiped body as shown in FIG. 1.

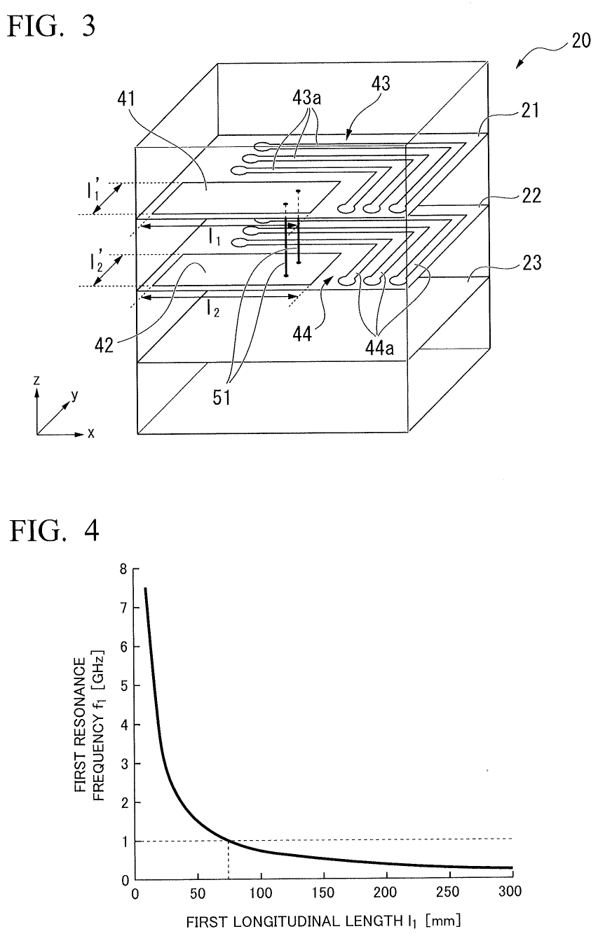

Hereinafter, a configuration of the circuit board 20 will be described with reference to FIGS. 2 and 3. FIG. 2 is a cross-sectional view of the circuit board 20 taken along the line F2-F2 shown in FIG. 1. FIG. 3 is a perspective view showing the circuit board 20 of the first embodiment.

The circuit board 20 is a so-called multilayer board. The circuit board 20 includes a first inner layer (a second conducting level) 21, a second inner layer (a third conducting level) 22, a third inner layer (a ground layer; a fourth conducting level) 23, a first outer layer (a first conducting level) 24, a second outer layer (a fifth conducting level) 25, a first insulating layer (a first insulating level) 31, a second insulating layer (a second insulating level) 32, a third insulating layer (a third insulating level) 33, and a fourth insulating layer (a fourth insulating level) 34. These layers (levels) are laminated in the order of the first outer layer 24, the first insulating layer 31, the first inner layer 21, the second insulating layer 32, the second inner layer 22, the third insulating layer 33, the ground layer 23, the fourth insulating layer 34, and the second outer layer 25 from one main surface toward the other main surface of the circuit board 20. However, the order, number and type of layers are not limited to the above example. The first inner layer 21 is an example of a “first layer.” The second inner layer 22 is an example of a “second layer.”

In FIG. 3, only the first inner layer 21, the second inner layer 22, and the ground layer 23 among the above layers are illustrated.

In the first inner layer 21, a first power supply pattern 41 and a first signal pattern 43 including a plurality of first signal lines 43a are formed. In the second inner layer 22, a second power supply pattern 42 and a second signal pattern 44 including a plurality of second signal lines 44a are formed. The first power supply pattern 41 and the second power supply pattern 42 are electrically connected to each other through vias 51. Also, although only two vias 51 are shown in FIG. 3, vias are appropriately formed (not shown) in addition to those vias. Further, at least one of the first power supply pattern 41 and the second power supply pattern 42 may be connected to an external power source (not shown).

Here, the “power supply pattern” is a conductive pattern that receives power from an external power source or the like and supplies power to other elements (electrical components) of the circuit board. The “signal pattern” is a conductive pattern including a plurality of signal lines which connect respective electrical component provided on a circuit board to each other.

The first power supply pattern 41 has, for example, a rectangular shape which is elongated in the x direction, extends having a first longitudinal length 1₁′ in a longitudinal direction (for example, the x direction), and extends having a first lateral length in a lateral direction (for example, the y direction) (see FIG. 3). Here, l₁ is larger than l₁′. However, the shape of the first power supply pattern 41 is not limited to the above example.

It should be also noted that the terms “longitudinal direction” and “lateral direction” imply that a length of the power supply pattern in a certain direction is larger than a length in another direction. The term “longitudinal length” means a distance between the farthest two parallel edges of the power supply pattern, and the term “longitudinal direction” means a direction along the “longitudinal length.” Further, the term “lateral length” means a distance between the closest two parallel edges of the power supply pattern, and the term “lateral direction” means a direction along the “lateral length.”

Similarly to the first power supply pattern 41, the second power supply pattern 42 also has, for example, a rectangular shape which is elongated in the x direction, extends having a second longitudinal length l₂ in the longitudinal direction (for example, the x direction), and extends having a second lateral length l₂′ in the lateral direction (for example, the y direction). Here, l₂ is larger than l₂′. However, the shape of the second power supply pattern 42 is not limited to the above example.

An area (l₁×l₁′) of the first power supply pattern 41 in the x-y plane and an area (1₂xl₂′) of the second power supply pattern 42 in the x-y plane may be substantially equal to each other, for example. However, the area of the first power supply pattern 41 may be different from the area of the second power supply pattern 42, In addition, the first power supply pattern 41 and the second power supply pattern 42 are formed to at least partially overlap with each other when viewed in the z direction. For example, when viewed in the z direction, half or more of the first power supply pattern 41 may overlap the second power supply pattern 42. Here, “half or more” is based on the area of the region where the power supply pattern is formed on the x-y plane. For example, when viewed in the z direction, the entire first power supply pattern 41 may overlap the second power supply pattern 42. Instead, when viewed in the z direction, the entire second power supply pattern 42 may overlap the first power supply pattern 41.

The first signal pattern 43 includes first signal lines 43a having an arbitrary shape. The second signal pattern 44 includes second signal lines 44a having an arbitrary shape. An example of the arrangement of the first signal lines 43a and the second signal lines 44a is shown in FIG. 3.

The third inner layer (ground layer) 23 is provided as a planar layer in which the entire layer functions as a ground. The ground layer 23 can be electrically connected to each electronic component (not shown) disposed on the first outer layer 24 and the second outer layer 25 through vias. Also, in the present embodiment, the ground layer 23 is provided adjacent to the second inner layer 22 on which the power supply pattern is formed. However, another inner layer may be additionally formed between the second inner layer 22 and the ground layer 23.

Also, in the present embodiment, the ground layer 23 is provided as a planar layer, but the ground pattern may be formed only in a portion of the layer. In this case, the ground pattern may be disposed to overlap at least one of the first power supply pattern 41 and the second power supply pattern 42 when viewed in the z direction, for example. The ground pattern may be disposed to be separated from the first power supply pattern 41 and the second power supply pattern 42 and not to overlap any power supply pattern when viewed in the z direction.

The first outer layer 24 is a surface layer exposed outside one of the main surfaces of the circuit board 20. A third signal pattern 45 including third signal lines 45a having an arbitrary shape is formed on the first outer layer 24, The third signal lines 45a connect respective electronic components (not shown) provided in the first outer layer 24 to each other. The third signal lines 45a may be electrically connected to the first signal lines 43a of the first inner layer 21 or the like through vias.

The second outer layer 25 is a surface layer exposed outside the main surface of the circuit board 20 on a side opposite to the first outer layer 24. On the second outer layer 25, a fourth signal pattern 46 including fourth signal lines 46a having an arbitrary shape is formed. The fourth signal lines 46a connect respective electronic components (not shown) provided in the second outer layer 25 to each other. The fourth signal lines 46a may be electrically connected to the second signal lines 44a of the second inner layer 22 or the like through vias.

The first insulating layer 31, the second insulating layer 32, the third insulating layer 33, and the fourth insulating layer 34 physically and electrically isolate the respective layers. The first insulating layer 31 is positioned between the first outer layer 24 and the first inner layer 21. The second insulating layer 32 is positioned between the first inner layer 21 and the second inner layer 22. The third insulating layer 33 is positioned between the second inner layer 22 and the ground layer 23. The fourth insulating layer 34 is positioned between the ground layer 23 and the second outer layer 25. These insulating layers may be made of, for example, glass fabric based epoxy resin of FR-4 (flame retardant type 4) grade, but are not limited thereto.

Also, in FIG. 3, the first outer layer 24, the second outer layer 25, the first insulating layer 31, the second insulating layer 32, the third insulating layer 33, and the fourth insulating layer 34 are not shown.

Next, dimensions of the first power supply pattern 41 and the second power supply pattern 42 will be described in detail.

As described above, the first power supply pattern 41 has the first longitudinal length li and the first lateral length l₁′. The second power supply pattern 42 has the second longitudinal length 1₂ and the second lateral length l₂′.

In general, in a case where the power supply pattern of the circuit board has a rectangular shape with a short side length a and a long side length b (a<b), interference with the signal frequency of the system occurs due to a resonance phenomenon caused by the power supply pattern, so that noise having a resonance frequency fₘₙ expressed by the following equations can be generated in the signal system of the circuit board.

$$\begin{matrix}{f}_{mn} = \frac{1}{2 π \sqrt{μ ɛ}} \sqrt{{( \frac{m π}{a} )}^{2} + {( \frac{n π}{b} )}^{2}} \\ = \frac{{c}_{0}}{2 π \sqrt{{μ}_{r} {ɛ}_{r}}} \sqrt{{( \frac{m π}{a} )}^{2} + {( \frac{n π}{b} )}^{2}}\end{matrix} \qquad [ Equation 1 ]$$

Here, μ is the magnetic permeability of the circuit board (that is the magnetic permeability of the insulating layers), ε is the electric permittivity of the circuit board (that is the electric permittivity of the insulating layers), c₀ is the speed of light in a vacuum, μᵣ is the specific magnetic permeability of the circuit board, εᵣ is the specific electric permittivity of the circuit board, m and n are integers of 0 or more.

If calculating fₘₙ from the smallest value to larger values, fₘₙ=f₀₀=0 when m=n=0. Next, when m=0 and n=1, fₘₙ becomes as follows.

$${f}_{01} = \frac{1}{2 π \sqrt{μ ɛ}} \sqrt{{( \frac{π}{b} )}^{2}} = \frac{1}{2 \sqrt{μ ɛ}} \cdot \frac{1}{b} \qquad [ Equation 2 ]$$

Also, when m=1 and n=0, fₘₙ becomes as follows.

$${f}_{10} = \frac{1}{2 π \sqrt{μ ɛ}} \sqrt{{( \frac{π}{a} )}^{2}} = \frac{1}{2 \sqrt{μ ɛ}} \cdot \frac{1}{a} \qquad [ Equation 3 ]$$

Here, since 1/a>1/b from a<b, f₀₁<f₁₀. Also, the value of when m≥1 and n≥1 is larger than f₀₁ and f₁₀. Therefore, the minimum fₘₙ excluding f₀₀ is f₀₁ (in the following, f₀₀ is not taken into account and f₀₁ is called the minimum fₘₙ).

In the present embodiment, the first longitudinal length l₁ and the first lateral length l₁′ of the first power supply pattern 41 correspond to b and a, respectively. Therefore, the first resonance frequency f₁ corresponding to the minimum resonance frequency fₘₙ=f₀₁ of the first power supply pattern 41 is expressed as follows using the first longitudinal length l₁.

$${f}_{1} = \frac{1}{2 \sqrt{μ ɛ}} \cdot \frac{1}{{l}_{1}} \qquad [ Equation 4 ]$$

In addition, the second longitudinal length 12 and the second lateral length l₂′ of the second power supply pattern 42 correspond to the above b and a, respectively. Therefore, the second resonance frequency f₂ corresponding to the minimum resonance frequency fₘₙ=f₀₁ of the second power supply pattern 42 is expressed as follows using the second longitudinal length l₂.

$${f}_{2} = \frac{1}{2 \sqrt{μ ɛ}} \cdot \frac{1}{{l}_{2}} \qquad [ Equation 5 ]$$

In the present embodiment, the first longitudinal length l₁ of the first power supply pattern 41 is selected to be f₁>1 GHz. In addition, the second longitudinal length l₂ of the second power supply pattern 42 is selected so as to satisfy f₂>1 GHz. Accordingly, the first longitudinal length l₁ and the second longitudinal length l₂ satisfy the following conditional equations.

$$\begin{matrix}{f}_{1} = \frac{1}{2 \sqrt{μ ɛ}} \cdot \frac{1}{{l}_{1}} > 1 GHz & [ Equation 6 ] \\ {f}_{2} = \frac{1}{2 \sqrt{μ ɛ}} \cdot \frac{1}{{l}_{2}} > 1 GHz & [ Equation 7 ]\end{matrix}$$

These conditional equations can also be rewritten as follows.

$${l}_{1} , {l}_{2} < \frac{1}{( 2 GHz ) \times \sqrt{μ ɛ}} = \frac{{c}_{0}}{( 2 GHz ) \times \sqrt{{μ}_{r} {ɛ}_{r}}} \approx \frac{150 mm}{\sqrt{{μ}_{r} {ɛ}_{r}}} \qquad [ Equation 8 ]$$

The dimensions of the power supply pattern satisfying such a condition will be specifically described with reference to FIG. 4 while taking the first power supply pattern 41 as an example.

FIG. 4 shows an example of the relationship of the first resonance frequency f₁ with respect to the first longitudinal length l₁ of the first power supply pattern 41.

Here, considering an example in which an FR-4 board is used, the specific magnetic permeability of the board is simply calculated as μᵣ=1 and the specific electric permittivity of the board is εᵣ=4.3. In this case, the relationship between the first resonance frequency f₁ and the first longitudinal length l₁ is as follows.

$${f}_{1} = ( 7.2 \times {10}^{7} m \text{/} s ) \times \frac{1}{{l}_{1}} \qquad [ Equation 9 ]$$

From the above, f₁=1 GHz (=1×10⁹/s) when l₁=72 mm. Therefore, in this example, in order to satisfy f₁>1 GHz, the first longitudinal length l₁ must satisfy l₁<72 mm. Conversely, if l₁<72 mm, the minimum resonance frequency f₁ of the first power supply pattern 41 is greater than 1 GHz.

Similarly, in order to satisfy f₂>1 GHz, the second longitudinal length l₂ must satisfy l₂<72 mm. Conversely, if l₂<72 mm, the minimum resonance frequency f₂ of the second power supply pattern 42 is greater than 1 GHz.

Therefore, in this example, the first longitudinal length l₁ of the first power supply pattern 41 is selected to be a length smaller than 72 mm such that f₁>1 GHz. In addition, the second longitudinal length l₂ of the second power supply pattern 42 is selected to be a length smaller than 72 mm such that f₂>1 GHz.

In a case where the material constituting the circuit board 20 is different from that of the above example, the magnetic permeability and the electric permittivity of the circuit board 20 are different, so that the allowable ranges of the first longitudinal length l₁ and the second longitudinal length l₂ are also different from the above example. Also in such a case, the first longitudinal length l₁ and the second longitudinal length l₂ are selected to satisfy the above-mentioned equations 6 and 7 as in the above example.

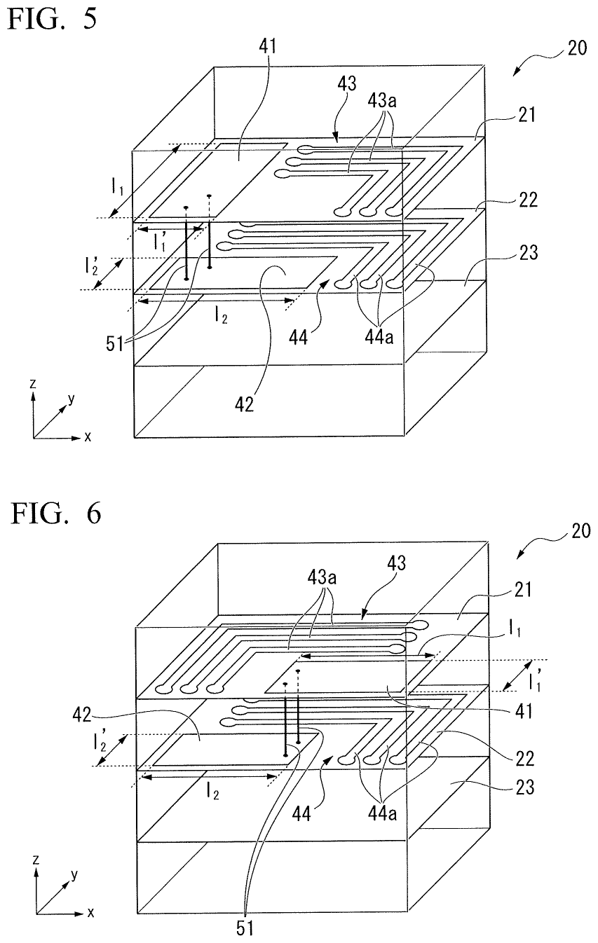

Next, a modification of the present embodiment will be described with reference to FIGS. 5 and 6.

FIG. 5 is a perspective view showing a first modification of the circuit board of the first embodiment.

The first modification shown in FIG. 5 differs from the example described above with reference to FIGS. 1 to 3 in that the first power supply pattern 41 extends in the y direction. Also, configurations other than those described below are the same as in the above example.

In the first modification, as shown in FIG. 5, the first power supply pattern 41 has a rectangular shape extending in the y direction, extends having the first longitudinal length l₁ in the longitudinal direction (the y direction), and extends having the first lateral length l₁′ in the lateral direction (the x direction) (l₁>l₁′). The second power supply pattern 42 has, for example, a rectangular shape which is elongated in the x direction, extends having the second longitudinal length l₂ in the longitudinal direction (the x direction), and extends having the second lateral length l₂′ in the lateral direction (the y direction) (l₂>l₂′). That is, the longitudinal direction (the y direction) of the first power supply pattern 41 and the longitudinal direction (the x direction) of the second power supply pattern 42 are different from each other (for example, substantially perpendicular to each other).

When viewed in the z direction, the first power supply pattern 41 and the second power supply pattern 42 are partially overlapped at their respective ends. A via 51 for electrically connecting the first power supply pattern 41 and the second power supply pattern 42 is formed in the overlapped portion. Also, at the other end of the first power supply pattern 41 not overlapping the second power supply pattern 42, a portion of the first power supply pattern 41 overlaps the second signal line 44a of the second signal pattern 44 of the second inner layer 22.

FIG. 6 is a perspective view showing a second modification of the circuit board of the first embodiment. The second modification shown in FIG. 6 is different from the example described above with reference to FIGS. 1 to 3 in that the position of the first power supply pattern 41 and the position of the second power supply pattern 42 are shifted in the x direction when viewed in the z direction. Also, configurations other than those described below are the same as in the above example.

In the second modification, as shown in FIG. 6, the first power supply pattern 41 is disposed to be shifted in the x direction with respect to the second power supply pattern 42 when compared with the first power supply pattern 41 shown in FIG. 3.

When viewed in the z direction, the first power supply pattern 41 and the second power supply pattern 42 are partially overlapped at their respective ends. A via 51 for electrically connecting the first power supply pattern 41 and the second power supply pattern 42 is formed in the overlapped portion.

At the other end of the first power supply pattern 41 not overlapping with the second power supply pattern 42, a portion of the first power supply pattern 41 overlaps the second signal line 44a of the second signal pattern 44 of the second inner layer 22. Similarly, at the other end of the second power supply pattern 42 not overlapping the first power supply pattern 41, a portion of the second power supply pattern 42 overlaps the first signal line 43a of the first signal pattern 43 of the first inner layer 21.

According to the above configuration, it is possible to provide an electronic device in which at least one (for example, both) of power supply quality (power integrity) and signal quality (signal integrity) is improved.

For example, the electronic device 1 according to the present embodiment includes the circuit board 20 including the first inner layer 21 and the second inner layer 22, and the power supply pattern of the circuit board 20 is divided into a plurality of power supply patterns (herein, the first power supply pattern 41 in the first inner layer 21 and the second power supply pattern 42 in the second inner layer 22).

Generally, in a case where board resonance due to a power supply pattern occurs, interference with the signal frequency of the system can cause noise to the signal system of the circuit board. However, in the present embodiment, the resonance frequency of the board resonance increases as the power supply pattern is divided into small sizes. In a case where the resonance frequency is high as described above, attenuation of noise due to the board resonance is fast, so that the adverse effect on the signal is often reduced in many cases. For this reason, dividing the power supply pattern can improve the signal quality.

On the other hand, if the area of the power supply pattern is reduced by decreasing the size of the power supply pattern, the impedance increases and the power supply quality may deteriorate in a way in which noise is generated in the voltage of the power supply, etc.

However, since the electronic device 1 of the present embodiment includes the circuit board 20 including a plurality of divided power supply patterns, it is possible to shorten the length of the power supply pattern in order to increase the resonance frequency while maintaining the area of the power supply pattern as a whole at the same level when compared to the circuit board in which the power supply pattern is extended without being divided. By suppressing a decrease in the area of the power supply pattern, an increase in impedance can be suppressed, so that the power supply quality can be improved.

As described above, in the present embodiment, by dividing the power supply pattern into a plurality of parts, it is possible to improve at least one (for example, both) of the power supply quality and the signal quality in the circuit board of the electronic device.

In order to suppress the influence of board resonance as described above, a capacitor (also referred to as a bypass capacitor) electrically connected to the power supply pattern may be provided on the surface layer or the like of the circuit board, However, in that case, a separate capacitor and a region for disposing the capacitor are required. According to the present embodiment, it is possible to improve the power supply quality and the signal quality while suppressing the increase of the area to the minimum without requiring such a capacitor or capacitor area. As a result, it is possible to reduce work man-hours and costs and to reduce the trouble of procuring components such as capacitors and the like. Further, freedom of disposition of electronic components, signal lines, etc. can be improved.

In the present embodiment, the first power supply pattern 41 extends having the first length l₁ in the first longitudinal direction of the first power supply pattern 41, and the second power supply pattern 42 extends having the second length l₂ in the second longitudinal direction of the second power supply pattern 42, and the first length l₁ and the second length l₂ satisfy the following conditional equations (μ: magnetic permeability of the circuit board 20, ε: electric pennittivity of the circuit board 20).

$$\begin{matrix}\frac{1}{2 \sqrt{μ ɛ}} \cdot \frac{1}{{l}_{1}} > 1 GHz & [ Equation 10 ] \\ \frac{1}{2 \sqrt{μ ɛ}} \cdot \frac{1}{{l}_{2}} > 1 GHz & [ Equation 11 ]\end{matrix}$$

According to such a configuration, since the minimum resonance frequency of the power supply pattern of the entire circuit board 20 is larger than 1 GHz, it is possible to suppress the resonance phenomenon caused by the power supply pattern at a frequency of 1 GHz or less.

In a case where the resonance frequency is 1 GHz or less, noise of the power supply caused by the resonance of the power supply pattern often exerts a large influence on the signal system as compared with the case where the resonance frequency is larger than 1 GHz. Conversely, in a case where the resonance frequency is greater than 1 GHz, the noise of the power supply due to the board resonance is easily attenuated in particular, so that the adverse effect on the signal system is often small in many cases. In the present embodiment, by selecting the size of the power supply pattern such that the resonance frequency of the power supply pattern is larger than 1 GHz, the influence on the signal system of the board resonance can be particularly restrained, so that the signal quality can be further improved.

Beside the above board resonance, an electromagnetic wave having a specific resonance frequency can be radiated by resonance between the power supply pattern and the ground layer. As a result, this electromagnetic wave may affect the operation of another electronic device. Conversely, in a case where an external electromagnetic wave having the same frequency as the resonance frequency of the circuit board exists, the circuit board may be affected by the external electromagnetic wave.

According to the present embodiment, it is also possible to select the length of the power supply pattern to avoid resonance frequencies at which such interference tends to occur. For example, in order to avoid interference with a frequency band (for example, 2.4 GHz band) for wireless communication, it is possible to select the length of the power supply pattern such that the resonance frequency of the board is not included in the frequency band. In this way, by shifting the frequency of the electromagnetic radiation as necessary, it is possible to suppress the influence of interference of electromagnetic waves.

In the above example, the power supply pattern is divided into two, but the power supply pattern may be divided into three or more. For example, the first power supply pattern may be formed in the first inner layer, the second power supply pattern may be formed in the second inner layer, the third power supply pattern may be formed in the third inner layer, and these may be electrically connected to each other through vias.

In the above example, the first inner layer 21 and the second inner layer 22 are disposed to be adjacent to each other with the second insulating layer 32 interposed therebetween. However, another layer may be additionally interposed between the first inner layer 21 and the second inner layer 22. For example, the ground layer 23 may be disposed between the first inner layer 21 and the second inner layer 22.

### Second Embodiment

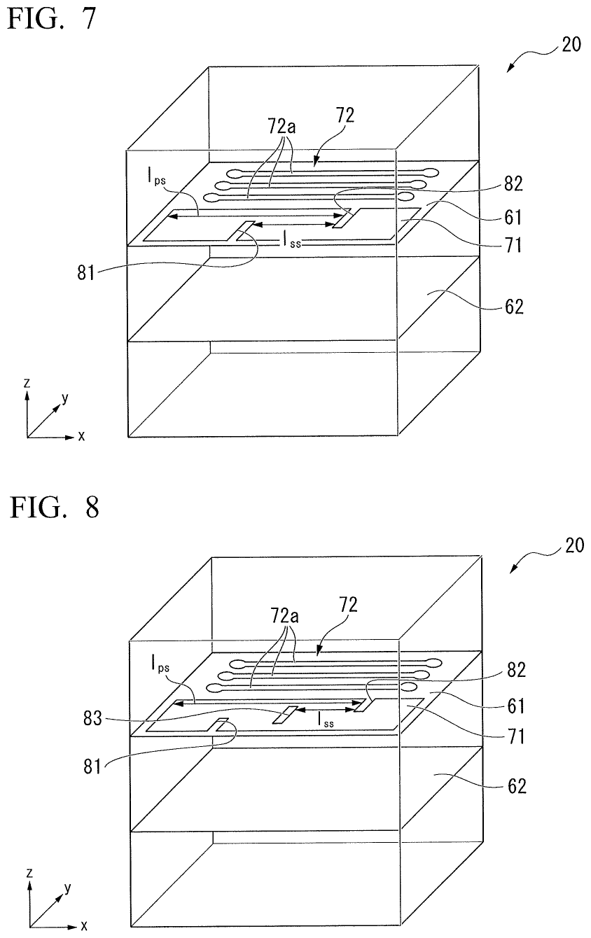

Next, a second embodiment will be described with reference to FIGS. 7 and 8.

The second embodiment is different from the first embodiment in that the power supply pattern is not divided into a plurality of layers but slits are formed in the power supply pattern instead. Also, configurations other than those described below are the same as those in the first embodiment.

FIG. 7 is a perspective view showing the circuit board 20 of the second embodiment.

The circuit board 20 includes one first inner layer 61 on which a power supply pattern is formed instead of the first inner layer 21 and the second inner layer 22 in the first embodiment. In FIG. 7, only the first inner layer 61 and a second inner layer (a ground layer) 62 are shown, and outer layers and insulating layers are omitted.

In the first inner layer 61, a power supply pattern 71 and a signal pattern 72 including a signal line 72a are formed.

The power supply pattern 71 has, for example, a rectangular shape which is elongated in the x direction. However, the shape of the power supply pattern 71 is not limited to the above example.

The power supply pattern 71 is connected to an external power supply (not shown).

In the power supply pattern 71, a first slit 81 and a second slit 82 are formed.

In other words, no power supply pattern is formed at the positions of the first slit 81 and the second slit 82. The first slit 81 and the second slit 82 extend in a direction that is different from (for example, is substantially perpendicular to) the longitudinal direction (for example, the x direction) of the power supply pattern 71. However, the power supply pattern 71 is not completely divided by the first slit 81 and the second slit 82. That is, none of the first slit 81 and the second slit 82 crosses the power supply pattern 71 from one end to the other end of the power supply pattern 71. The first slit 81 extends beyond a central portion in the lateral direction of the power supply pattern 71 from one end in the lateral direction of the power supply pattern 71. The second slit 82 extends beyond a central portion in the lateral direction of the power supply pattern 71 from the other end in the lateral direction of the power supply pattern 71. However, one of the first slit 81 and the second slit 82 may not extend beyond the central portion in the lateral direction.

When viewing the power supply pattern 71 in the longitudinal direction (the x direction) of the power supply pattern 71, at least one of the first slit 81 and the second slit 82 is at any position in a transverse direction (the y direction) of the power supply pattern 71. In other words, if a straight line parallel to the longitudinal direction were drawn from one end to the other end in the longitudinal direction of the power supply pattern 71, this straight line would intersect at least one of the first slit 81 and the second slit 82.

The signal pattern 72 includes a signal line 72a having an arbitrary shape. An example of disposition of the signal line 72a is shown in FIG. 7.

Next, the arrangement of the first slit 81 and the second slit 82 in the power supply pattern 71 will be described in detail,

The length lₚₛ in FIG. 7 indicates the maximum length between the outer edge of the power supply pattern 71 and the first slit 81 or the second slit 82 in the longitudinal direction of the power supply pattern 71 (hereinafter referred to as “maximum length lₚₛ between the pattern outer edge and the slit”). Here, the length in the longitudinal direction between one end (the left end in FIG. 7) of the power supply pattern 71 in the longitudinal direction and the second slit 82 is the maximum length lₚₛ between the pattern outer edge and the slit.

Also, the length lₛₛ in FIG. 7 shows the maximum length (hereinafter referred to as “maximum length lₛₛ between slits”) between the slits in the longitudinal direction of the power supply pattern 71 (here, between the first slit 81 and the second slit 82). Here, since the first slit 81 and the second slit 82 are substantially perpendicular to the longitudinal direction of the power supply pattern 71, the length in the longitudinal direction between the first slit 81 and the second slit 82 is all constant, so that this is the maximum length lₛₛ between the slits.

The power supply pattern 71 including slits can generate resonance at a resonance frequency corresponding to the maximum length lₚₛ between the pattern outer edge and the slit and the maximum length lₛₛ between the slits. As described with reference to the first embodiment, the resonance frequencies fₚₛ and fₛₛ corresponding to these lengths lₚₛ and lₛₛ are expressed as follows and also satisfy the following conditional equations as in the first embodiment.

$$\begin{matrix}{f}_{ps} = \frac{1}{2 \sqrt{μ ɛ}} \cdot \frac{1}{{l}_{ps}} > 1 GHz & [ Equation 12 ] \\ {f}_{ss} = \frac{1}{2 \sqrt{μ ɛ}} \cdot \frac{1}{{l}_{ss}} > 1 GHz & [ Equation 13 ]\end{matrix}$$

By the same equational modification as in the first embodiment, the conditions of lₚₛ and lₛₛ to satisfy the above conditional equations are expressed as follows.

$${l}_{ps} , {l}_{ss} < \frac{1}{( 2 GHz ) \times \sqrt{μ ɛ}} = \frac{{c}_{0}}{( 2 GHz ) \times \sqrt{{μ}_{r} {ɛ}_{r}}} \approx \frac{150 mm}{\sqrt{{μ}_{r} {ɛ}_{r}}} \qquad [ Equation 14 ]$$

Next, a modification of the second embodiment will be described with reference to FIG. 8.

FIG. 8 is a perspective view showing a modification of the circuit board 20 of the second embodiment.

The modification shown in FIG. 8 is different from the example described above with reference to FIG. 7 in that the number of slits formed in the power supply pattern 71 is three. Also, configurations other than those described below are the same as in the above example.

In FIG. 8, a first slit 81, a second slit 82, and a third slit 83 are formed in the power supply pattern 71. The first slit 81 extends from one end in the lateral direction of the power supply pattern 71 toward the central portion in the lateral direction of the power supply pattern 71. The second slit 82 extends from the other end in the lateral direction of the power supply pattern 71 toward the central portion in the lateral direction of the power supply pattern 71. The third slit 83 is positioned between the first slit 81 and the second slit 82 in the longitudinal direction (for example, in the vicinity of the central portion in the longitudinal direction of the power supply pattern 71), separated from the outer edges of the power supply pattern 71, and extends around the vicinity of the central portion in the lateral direction of the power supply pattern 71.

However, the arrangement of these slits is not limited to the above example. For example, the third slits 83 may extend from either end in the lateral direction of the power supply pattern 71. In addition, for example, the third slit 83 extends from one end in the lateral direction of the power supply pattern 71 toward the central portion in the lateral direction of the power supply pattern 71, and instead, the first slit 81 or the second slit 82 may be separated from the outer edges of the power supply pattern 71 and extend around the vicinity of the central portion in the lateral direction.

In FIG. 8, the maximum length lₚₛ between the pattern outer edge and the slit is the length in the longitudinal direction between one end (the left end in FIG. 8) of the power supply pattern 71 in the longitudinal direction and the second slit 82. The maximum length lₛₛ between the slits is the length in the longitudinal direction between the third slit 83 and the second slit 82.

Similarly to the example of FIG. 7, the maximum length lₚₛ between the pattern outer edge and the slit and the maximum length lₛₛ between the slits satisfy Equations 12 to 14.

In the present embodiment, the power supply pattern 71 of the circuit board 20 has a plurality of slits extending in a direction that is different from the longitudinal direction of the power supply pattern 71, and when viewing the power supply pattern 71 in the longitudinal direction, at least one of a plurality of slits is at any position in a transverse direction of the power supply pattern 71.

According to this configuration, by forming slits in the power supply pattern, the resonance frequency of the power supply pattern can be increased. Thus, as in the first embodiment, the signal quality can be improved.

Further, in the present embodiment, it is possible to increase the resonance frequency by forming the slits while maintaining the area of the power supply pattern to the same level as a whole as compared with the circuit board having the same size power supply pattern. By suppressing a decrease in the area of the power supply pattern, an increase in impedance can be suppressed, so that the power supply quality can be improved.

As described above, in this embodiment, by forming a plurality of slits in the power supply pattern, it is possible to improve at least one (for example, both) of the power supply quality and the signal quality in the circuit board of the electronic device. Further, as compared with the first embodiment, it is not necessary to provide a power supply pattern over two layers, so that one layer in which the power supply pattern is formed can be omitted. As a result, the manufacturing cost can be reduced.

In the present embodiment, the maximum length lₚₛ between the outer edge of the power supply pattern 71 and any slit among the plurality of slits in the longitudinal direction, and the maximum length lₛₛ between any two slits among the plurality of slits in the longitudinal direction satisfy the following conditional equations (μ: magnetic permeability of the circuit board 20, ε: electric permittivity of the circuit board 20).

$$\begin{matrix}\frac{1}{2 \sqrt{μ ɛ}} \cdot \frac{1}{{l}_{ps}} > 1 GHz & [ Equation 15 ] \\ \frac{1}{2 \sqrt{μ ɛ}} \cdot \frac{1}{{l}_{ss}} > 1 GHz & [ Equation 16 ]\end{matrix}$$

According to this configuration, by selecting the dimension of the power supply pattern such that the resonance frequency of the power supply pattern is larger than 1 GHz, the influence on the signal system of the board resonance can be particularly restrained, so that the signal quality is further improved.

In the present embodiment, at least one of the plurality of slits is separated from the outer edges of the power supply pattern 71 and is provided inside the power supply pattern 71.

According to this configuration, as compared with the case where all the slits extend from one end in the lateral direction of the power supply pattern, the portion through which the current flowing in the power supply pattern passes at the slit position can be increased. As a result, it is possible to reduce the possibility that the power supply pattern is damaged as the current passes through the slit position, and eventually increase the amount of current that can flow.

In the above example, two or three slits are formed in the power supply pattern 71, but four or more slits may be formed. As the number of slits increases, the length of each slit can be made shorter than when the number of slits is small, and accordingly, it is possible to relatively increase the width of the portion where the slit is not formed at the slit position of the power supply pattern. As a result, it is possible to reduce the possibility that the power supply pattern is damaged as the current passes through the slit position, and eventually increase the amount of current that can flow.

In the above example, the circuit board 20 has a multilayer structure, but may have a single layer structure including only the first inner layer 61. In this case, the ground pattern can also be formed on the first inner layer 61.

Hereinafter, modifications common to the first embodiment and the second embodiment will be described.

In the above example, the longitudinal direction of the power supply pattern is substantially parallel to the x direction or the y direction, but may be a direction inclined with respect to the x direction and the y direction. For example, in the first embodiment, the longitudinal direction of the first power supply pattern 41 may be substantially parallel to the x direction and the longitudinal direction of the second power supply pattern 42 may form an angle of 45 degrees with respect to the x direction.

In the above example, the layer on which the power supply pattern is formed is provided as a layer inside the circuit board 20, but it may be provided as a surface layer exposed to the outside of the circuit board 20.

In the above example, the first outer layer 24 and the second outer layer 25 are formed as a surface layer exposed to the outside of the circuit board 20, but at least a portion of the first outer layer 24 and the second outer layer 25 may be covered by a shield layer or a barrier layer or the like.

In the above example, electrical connection between layers is made through vias that do not penetrate all the layers of the board, but vias penetrating through all the layers of the board may be used.

Although the first embodiment and the second embodiment have been described separately, both embodiments may be combined. For example, slits as in the second embodiment may be formed in the second power supply pattern 42 in the first embodiment. In this case, the second power supply pattern 42 may be formed such that the entire length of the power supply pattern in the longitudinal direction is longer than that in the first embodiment.

According to at least one embodiment described above, it may be possible to provide an electronic device with improved signal quality due to adjusting the dimension in the longitudinal direction of the power supply pattern by dividing the power supply pattern or forming the slits.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising
a board including a first layer and a second layer, wherein
the first layer includes a first power supply pattern,
the second layer includes a second power supply pattern, the second power supply pattern being electrically connected to the first power supply pattern, and
when viewed in a thickness direction of the board, half or more of the first power supply pattern overlaps the second power supply pattern, or at least a portion of the first power supply pattern overlaps a signal line provided in the second layer.

2. The electronic device according to claim 1, wherein
the first power supply pattern has a first length l₁ in a first longitudinal direction of the first power supply pattern,
the second power supply pattern has a second length l₂ in a second longitudinal direction of the second power supply pattern, and
the first length l₁ and the second length l₂ satisfy the following conditional equations (μ: magnetic permeability of the board, ε: electric permittivity of the board).
$$\begin{matrix}\frac{1}{2 \sqrt{μ ɛ}} \cdot \frac{1}{{l}_{1}} > 1 GHz & [ Equation 1 ] \\ \frac{1}{2 \sqrt{μ ɛ}} \cdot \frac{1}{{l}_{2}} > 1 GHz & [ Equation 2 ]\end{matrix}$$

3. The electronic device according to claim 1, wherein
when viewed in the thickness direction of the board, an entire first power supply pattern overlaps the second power supply pattern, or an entire second power supply pattern overlaps the first power supply pattern.

4. The electronic device according to claim 1, wherein
the first power supply pattern extends in a first longitudinal direction,
the second power supply pattern extends in a second longitudinal direction, and
the first longitudinal direction and the second longitudinal direction are different from each other.

5. An electronic device comprising
a board including a power supply pattern, wherein
the power supply pattern includes a plurality of slits, the plurality of slits extending in a direction that is different from a longitudinal direction of the power supply pattern, and
when viewing the power supply pattern in the longitudinal direction, at least one of the plurality of slits is at any position in a transverse direction of the power supply pattern.

6. The electronic device according to claim 5, wherein
a maximum length lₚₛ between an outer edge of the power supply pattern and an arbitrary slit among the plurality of slits in the longitudinal direction and a maximum length lₛₛ between arbitrary two slits among the plurality of slits in the longitudinal direction satisfy the following conditional equations (μ: magnetic permeability of the board, ε: electric permittivity of the board).
$$\begin{matrix}\frac{1}{2 \sqrt{μ ɛ}} \cdot \frac{1}{{l}_{ps}} > 1 GHz & [ Equation 3 ] \\ \frac{1}{2 \sqrt{μ ɛ}} \cdot \frac{1}{{l}_{ss}} > 1 GHz & [ Equation 4 ]\end{matrix}$$

7. The electronic device according to claim 5, wherein
an entire perimeter of the power supply pattern is defined by outer edges of the power supply pattern, and
at least one of the plurality of slits is separated from the outer edges of the power supply pattern and is provided inside the power supply pattern.
